(19) United States
(12) Patent Application Publication
(10) Pub. No.: US 2025/0247107 A1
(43) Pub. Date: Jul. 31, 2025

(54) ASSEMBLY OF A PULSE-WIDTH CONTROLLED VECTOR-MATRIX MULTIPLICATION UNIT HAVING CAPACITIVE ELEMENTS AND METHOD FOR CONTROLLING SAID ASSEMBLY

(71) Applicant: SEMRON GmbH, Dresden (DE)

(72) Inventors: Kai-Uwe Demasius, Dresden (DE); Vadim Pozhidaev, Reutlingen (DE)

(21) Appl. No.: 19/182,380

(22) Filed: Apr. 17, 2025

Related U.S. Application Data
(63) Continuation of application No. PCT/EP2023/079385, filed on Oct. 20, 2023.

(30) Foreign Application Priority Data
Oct. 20, 2022 (EP) 22202657.7
Oct. 20, 2023 (WO) PCT/EP2023/079385

(51) Int. Cl. H03M 1/82; G04F 10/00

(52) U.S. Cl. CPC H03M 1/82; G04F 10/005

(57) ABSTRACT

An arrangement of a pulse-width controlled vector-matrix multiplication unit and a method for its operation are disclosed. The system includes an input block connected to word lines of a matrix formed from non-volatile adjustable capacitors, and output blocks including amplifiers with inverting inputs and feedback capacitors with parallel switches. A voltage ramp generator is coupled to the word lines via switches that are controlled by the input pulse width. The amplifier in the output block operates as a non-inverting amplifier in conjunction with the matrix capacitors. A second phase of operation involves a reference capacitor and a reverse voltage ramp generator connected to the inverting input of the amplifier. The arrangement can improve energy efficiency and analog computation accuracy by implementing a comparator design within a dual-ramp timing architecture.

### CROSS-REFERENCE TO RELATED APPLICATIONS

This application is a continuation-by-pass of PCT/EP2023/079385, filed Oct. 20, 2023, entitled, “ASSEMBLY OF A PULSE-WIDTH-CONTROLLED VECTOR-MATRIX MULTIPLICATION UNIT HAVING CAPACITIVE ELEMENTS AND METHOD CONTROLLING SAID ASSEMBLY,” which claims priority to European Patent Application No. 22202657.7, filed Oct. 20, 2022, the disclosures of which are incorporated herein by reference in their entirety.

### FIELD OF THE INVENTION

The invention relates to an assembly of a pulse-width controlled vector matrix having a multiplication unit according to one or more of the described embodiments. The invention also relates to a method for controlling an assembly of a pulse-width controlled vector matrix having a multiplication unit according to one or more of the described embodiments.

### BACKGROUND

In recent years, there has been increasing interest in the execution of analog vector-matrix multiplications by means of storage cells, which represent a multiplicand. The storage cells are arranged in matrix form, and represent coefficients, and input values are applied on the horizontal lines, which are word lines. The accumulation operation is generally executed according to Kirchhoff's law, wherein the output currents of storage cells are totalized.

Assemblies of this type are primarily applied in the calculation of artificial neural networks or the solution of differential equations.

One option is the employment of non-volatile memories such as e.g. resistive memory devices (e.g. Ielmini et al.: “In-memory computing with resistive switching devices”. Nature Electronics, 2018). Multiplication is executed using Ohm's law wherein, for example, a voltage is applied to the word lines of the matrix and the totalized currents are measured from the bit line of the matrix.

According to this approach, an analog vector-matrix multiplication is executed, and a conversion of digital data into analog input signals for the word lines and a conversion of analog output signals into digital data on the bit lines is necessary, in order to enable the combination of the multiplication unit with conventional digital processing.

In patent EP3523805B1 and the publication of Demasius et al.: “Energy-efficient memcapacitor devices for neuromorphic computing”. Nature Electronics, 2021, in addition to the above-mentioned resistive non-volatile memory devices, capacitive non-volatile memories are also presented. These are based upon the principle whereby the capacitance of a capacitor can be freely adjusted, and capacitance cannot be saved in a volatile arrangement. In comparison with resistive components, capacitive components provide an advantage, in that they barely assume any static current consumption and have a superior signal-to-noise ratio. Thus, with an equivalent comparative signal quality to resistive components, a lower readout voltage can be employed, which employment is also associated with a lower dynamic energy consumption.

Various options are available for the digital-analog and analog-digital converters (ADCs) which are required for this purpose: parallel converters, successive approximation registers (SAR)-ADCs or integrated converters. In analog vector-matrix multipliers, in the majority of cases, a parallel converter or a SAR ADC is employed (Caselli et al.: “Memory Devices and A/D Interfaces: Design Tradeoffs in Mixed-Signal Accelerators for Machine Learning Applications”. IEEE, 2022). The parallel converter has an advantage if a high speed is required, and the SAR ADC is advantageous if energy efficiency is the key focus. However, both types of ADC have a disadvantage, in that a large amount of space is required and, in the case of the SAR ADC, a complex digital control logic. For matrices with analog storage components, however, bit lines are lined up in a close-packed arrangement and, in order to enable an advantage over digital circuits, it is advantageous if ADCs which are connected to the bit lines also assume a compact design. This is particularly important in the context of the requisite compliance with design rules associated with the design of integrated circuits (e.g. minimum clearances between transistors and metallic conductors) wherein, in a close-packed alignment, and the more complex and larger the ADC circuit, the more difficult compliance with these rules will be.

In U.S. Pat. No. 11,409,045B2, a ramp-type ADC is employed in conjunction with resistive components. The output current of the bit line is integrated according to U.S. Pat. No. 11,409,045B2, or converted into a voltage by means of an inverting amplifier according to US2021271732A1. This voltage is then compared with a ramp signal and converted into a pulse length by means of an analog comparator. The pulse length is converted into a binary signal by means of a register.

ADCs operating by the dual-ramp method have an integration phase, in which the bit line current is integrated (first phase) and, thereafter, a de-integration phase (second phase), in which the state-of-charge of the integrator is cleared. The time interval required for the restoration of the integrator to the original voltage is converted into a pulse length by means of a comparator, and is registered once more. An exemplary embodiment having current sources for resistive non-volatile memories is included in patent application US 2020234111 A1. Dual-ramp ADCs provide an advantage in comparison with single-ramp ADCs, in that integration capacity is reduced and significantly lower ageing-and temperature-dependence occurs. However, this application does not explain the use of capacitive non-volatile memories, which provide the advantage of a significantly reduced energy consumption, as these can no longer be employed as a current source.

In the publication of Luo et al.: “Design and Optimization of Non-Volatile Capacitive Crossbar Array for In-Memory Computing”. IEEE Transactions on Circuits and Systems, 2022 the employment of a programmable capacitive non-volatile memory was disclosed, wherein accumulated charges are integrated by means of an operational amplifier. This publication also includes an array of reference capacitors which, however, are employed for the resolution of this issue with a restrictive dynamic (on/off) ratio. This publication did not include any reference to a dual-ramp ADC having an integration phase and a discharge phase.

In patent application US20220027130A1 an assembly was disclosed having an integrator on the bit lines, and incorporating capacitances for the representation of the weighting matrix. Encoded input values can also be applied as pulse widths to the word lines, wherein either constant voltage pulses or current pulses are assumed. An employment of an integration phase and a discharge phase has also been disclosed. Both phases are based either upon constant voltages, which are applied to an admittance, or upon current sources wherein, in the discharge phase, a reference admittance or a reference current source is employed.

The above-mentioned US20220027130A1 describes no conversion of input pulse widths into a variable voltage value (only reference to a digital-to-time converter is included), nor of any capacitive non-volatile memories which can be programmed to an analog capacitance value. Instead, constant reference capacitors having switches are connected in parallel, such that various weighting states can be achieved. A disadvantage of this arrangement is the large amount of space which is required for the representation of multiple states, and that each storage cell is comprised of at least one capacitor and one switch. Additionally, according to the patent, integration with capacitive weightings is executed over a number of pulses, which involves a high consumption of energy. The proposed integration and discharge by means of current sources or admittances also involves a high consumption of energy.

The analog comparator in ramp-type ADCs can be, for example, a further operational amplifier circuit or a differential amplifier, as described in patent application US2020234111A1. However, this has a disadvantage, in that a static current consumption is required, and this type of ADC has no further advantage with respect to energy efficiency. A further option would be a dynamic latch-based comparator which, however, e.g. at an 8-bit value, requires 256-fold switching, thus signifying a high dynamic energy consumption. In the publication of Jendernalik et al.: “An Ultra-Low-Energy Analog Comparator for A/D Converters in CMOS Image Sensors”. Circuits Syst Signal Process, 2017, an energy-efficient comparator for image sensors was presented, featuring dynamic current consumption at the switchover time point only. To this end, an input transistor is employed which, according to the gate-source voltage differential, generates a discharge current for a charged capacitance, and executes a switchover of an associated output transistor, immediately the threshold voltage of the input transistor has been exceeded. The disadvantage of this comparator is the wide scatter band of properties of the input transistor, according to temperature and manufacturing conditions.

### SUMMARY OF THE INVENTION

Accordingly, the object of the present invention has been the development of an architecture for an analog vector-matrix multiplication unit which employs capacitive non-volatile storage components, wherein the dual-ramp ADC is adapted for this purpose, and energy efficiency is increased by an improved analog comparator employing the dual-ramp method.

According to the invention, for the fulfilment of this objective, network weights are comprised of programmable non-volatile adjustable capacitors, a further time-to-voltage converter is arranged down-circuit of the digital-to-time converter, and a reference capacitor for executing the discharge phase with a reference voltage ramp is provided.

The non-volatile storage components are comprised of adjustable capacitors, and the input block contains switches which connect a voltage ramp generator to the word lines, wherein the switch is configured to be controlled by the input pulse length, and the amplifier in the output block with a back-coupled capacitance functions as a non-inverting amplifier, together with the adjustable capacitors of the matrix, and the capacitances of the adjustable capacitors are totalized, wherein the output voltage of the amplifier is determined by the capacitance ratio, and the reference for a second phase, which is connected to the inverting input of the amplifier, is comprised of a reference capacitor having a connected reverse voltage ramp generator.

This means that the adjustable capacitors (Cₘ) are connected in parallel with the non-inverting input of the amplifier, and the adjustable capacitors form the elements of the matrix. The adjustable capacitors are connected by means of the word lines to voltage ramp generators which are controlled by the input pulses, such that voltage ramps assume a different length on the adjustable capacitors. The output voltage on the inverting amplifier is thus determined from the input ramp voltage (Vᵣₐₘₚ) and the integration capacitor (Cᵢₙₜ), as follows:

$${V}_{out} = - \frac{\sum {C}_{m}}{{C}_{int}} \cdot {V}_{ramp}$$

In a second phase, further to the first input ramp, by means of a reverse ramp on a reference capacitor, the previously generated output voltage is suppressed as follows:

$${V}_{out , 2} = \frac{{C}_{ref}}{{C}_{int}} \cdot {V}_{ramp}$$

The duration of this second phase is determined by means of a comparator, and corresponds to the output pulse length.

In a further favorable embodiment, the matrix is comprised of differential elements, each having a positive and a negative adjustable capacitor, and the positive and negative adjustable capacitors are connected to a common bit line and have a respective word line which, in the input block, is associated with a respective switch, which switches are connectively configured with reverse voltage ramps and are controllable by the same input pulse lengths.

The weights of a neural network are thus split into positive and negative values, each having a separate word line and, in each case, reverse voltage ramps are connected, such that subtraction is executed in the matrix itself, which represents an advantage over the prior art, in which a differential amplifier is customarily employed for two separate bit lines. Expressed as a formula, this gives the following for the output voltage of the amplifiers, with the positive (V_{ramp,+}) and negative (V_{ramp,-}) voltage ramp, and the positive (C_{m,+}) and negative (C_{m,-}) adjustable capacitors:

$${V}_{out} = - \frac{\sum {C}_{m , +}}{{C}_{int}} \cdot {V}_{ramp , +} - \frac{\sum {C}_{m , -}}{{C}_{int}} \cdot {V}_{ramp , -}$$

According to one embodiment, the reverse voltage ramps are connected to one or more further switches, which are configured such that the reverse voltage ramps can be interchanged, if the input pulse length carries a different sign.

In this manner, for example, both the negative and the positive voltage ramp can be connected to the positive adjustable capacitor, or conversely to the negative adjustable capacitor. Thus, in combination with the positive and negative adjustable capacitors, a four-quadrant multiplication is enabled in the matrix. In a further embodiment, a further offset capacitor is connected to the inverting input of the amplifier, which is connectively configured with a further voltage ramp, such that an offset of the output voltage of the amplifier is achieved. The purpose of this arrangement originates from the invariably limited voltage range of the amplifier such that, if the latter commences in the lower voltage range in phase 1, capability for the coverage of a negative voltage range would not be provided. To this end, a further offset capacitor having a voltage ramp is connected at the input of the amplifier. A displacement of the starting output voltage is thus achieved, such that a coverage of negative voltage ranges is also enabled.

In a further embodiment, one comparator input is connected to a capacitor, which is moreover connected by means of a switch to a voltage ramp generator, wherein the switch is configured to be controlled by the comparator output, and the other comparator input is connected to the output of the amplifier.

A typical comparator has an offset voltage and, additionally, the amplifier typically also has an offset voltage, which is dependent upon the preferred amplifier topology. This offset voltage can vary with temperature, but also over the manufacturing process. Particularly in the comparator structure preferred herein (next embodiment), the threshold voltage of the input transistor varies substantially. A variation of offset voltages would result in an altered output pulse width of the comparator, as a result of the switching thereof at different time points. In this embodiment, an assembly is described which scans the offset voltage of the comparator and of the amplifier on a capacitor by means of a connected voltage ramp, such that the subtraction thereof is executed.

In a further favorable embodiment, the comparator is comprised of an input transistor, wherein one input of the comparator is connected to the source terminal and the other input of the comparator is connected to the gate terminal of the input transistor and the drain terminal of the input transistor is connected to a capacitor which, optionally, can also be a stray capacitance of a transistor, and to a gate terminal of a further output transistor, wherein the capacitor and the output of the output transistor are configured such that these can be pre-charged in advance of a comparative phase.

Ultimately, the comparator is comprised of an input transistor which generates a discharge current which is dependent upon the differential voltage of the two inputs (the gate and source terminals). This discharge current discharges a capacitance which is connected to the gate terminal of an output transistor and which, with effect from a specific point, executes a switchover of the output transistor, which corresponds to the end of the output pulse length. This time point is achieved, for example, if the differential voltage (V_{GS}) at the input exceeds the threshold voltage (V_{T}):

V_{GS}≥V_{T}

The advantage of this comparator is that a dynamic energy consumption only occurs in a one-off manner at the switchover time point. This distinguishes the comparator vis-à-vis other dynamic comparators. However, the threshold voltage is subject to a wide variation, which can be resolved by the preceding embodiment.

According to a further embodiment, a register is connected to the output of the comparator. The output pulse length is thus converted into a binary number. According to a further embodiment, the output of the comparator is connected to a conversion table, which is configured to be controlled by a pulse generator. The advantage of this arrangement is that, in comparison with a binary register, arbitrary numbers can be entered in the conversion table, and any non-linearities offset accordingly. It is also conceivable that the non-linear activation function, e.g. ReLU or Sigmoid, can be represented in a conversion table of this type.

Embodiments of the method are described in greater detail hereinafter:

According to a favorable embodiment, in a first phase, a voltage ramp is applied to the bit lines of the matrix, which is controlled by the input pulse length, and non-volatile adjustable capacitors of the matrix along the bit line are totalized and, in a second phase, via a reference capacitor, a reverse voltage ramp is applied to the inverting input of the amplifier, and the comparator outputs a pulse length, until such time as the output voltage of the inverting amplifier is restored to the original voltage. Ultimately, the input-side voltage ramp is converted into an output voltage ramp on the amplifier by means of the following capacitance ratio, in a first step:

$${V}_{out} = - \frac{\sum {C}_{m}}{{C}_{int}} \cdot {V}_{ramp}$$

In a second phase, this ramp is then suppressed by means of a reference capacitor:

$${V}_{out , 2} = \frac{{C}_{ref}}{{C}_{int}} \cdot {V}_{ramp}$$

Given that, although the gradient and the end point of the output voltage ramp of the amplifier can vary according to the stored adjustable capacitance and the input pulse length, the ramp of the second phase consistently remains constant, the inverting amplifier is restored to its original voltage at different time points. This time point is ascertained by means of the comparator, and is output in the form of a pulse length.

According to a further embodiment of the method, the word lines of the positive and the word lines of the negative adjustable capacitors are charged with reverse voltage ramps, although the voltage ramps of the word lines of a matching matrix element, comprised of a positive and a negative adjustable capacitor, are controlled by means of the same input pulse length.

According to a further embodiment of the method, the reverse voltage ramps are interchanged, such that the reverse voltage ramp is applied to the word lines of the positive and negative adjustable capacitors, in the event that the input signal carries a different sign. This enables a four-quadrant multiplication, as both positive and negative input values are now possible. Accordingly, positive and negative elements of the matrix are thus subtracted in the matrix itself, which is advantageous in comparison with implementations involving a differential amplifier, as the latter requires significantly more space.

According to a further embodiment of the method, a voltage ramp is connected to one comparator input which simultaneously charges a capacitor, and this voltage ramp is interrupted immediately the switchover of the comparator output is executed, and the capacitor saves the scanned offset voltage. By means of this method, temperature and process fluctuations are compensated.

According to a further embodiment of the method, in a first phase, the capacitor and the output of the output transistor are pre-charged with a reset signal and, in a second phase, the capacitor is discharged by means of the input transistor, which is controlled by the voltage differential of the two inputs, and the output transistor executes a switchover, immediately the threshold voltage of the input transistor is exceeded.

This form of employment of the comparator enables a significantly lower energy consumption, as dynamic energy consumption only occurs at the switchover time point.

### BRIEF DESCRIPTION OF THE DRAWINGS

Favorable embodiments are illustrated hereinafter:

FIG. 1: Shows an overview of the storage matrix, having an input and output block;

FIG. 2: Shows the mode of operation of the output block;

FIG. 3: Shows offset voltage scanning by means of the comparator; and

FIG. 4: Shows a circuit diagram of a potential comparator.

### DETAILED DESCRIPTION

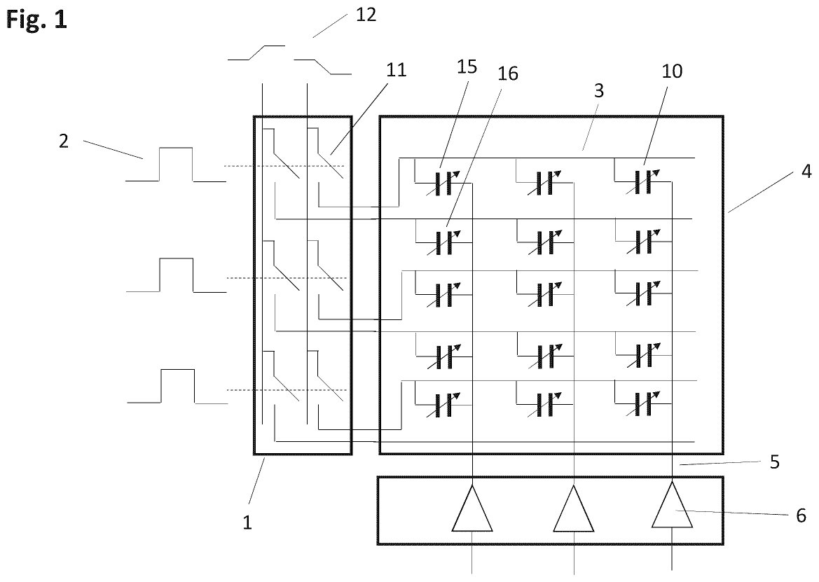

In FIG. 1, the matrix having non-volatile storage components (4) and a connected input (1) and output block (6) is represented. These are respectively connected to the word lines (4) and the bit lines (5). Within the matrix (4), adjustable capacitors (10) are employed, which are divided into positive (15) and negative (16) capacitors. The adjustable capacitors (10) are totalized along the bit line (5). The word lines are provided which voltage ramps (12) which, for positive (15) and negative (16) capacitors, assume an inverse gradient. The length of voltage ramps is controlled by means of switches (11) in the input block and by the input pulse length (2).

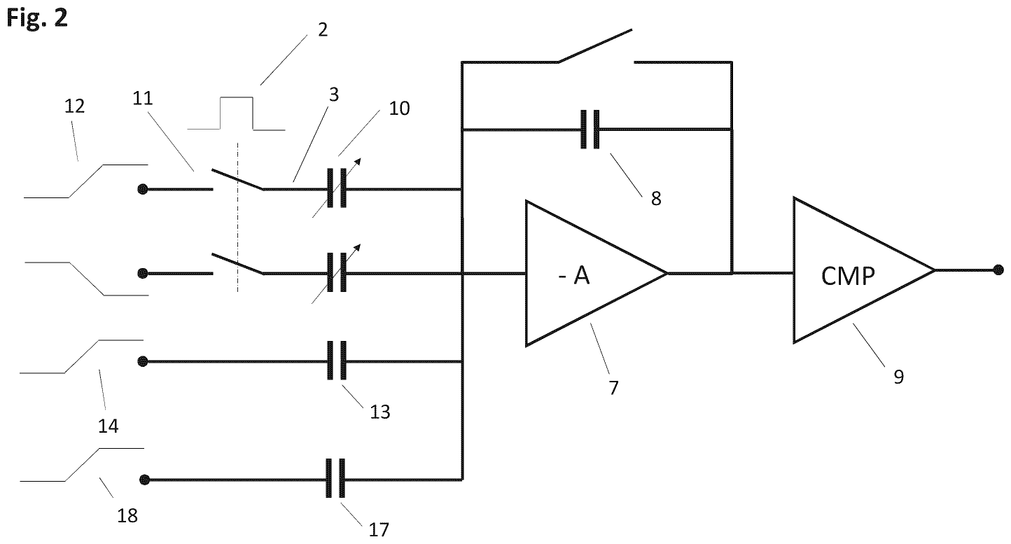

In FIG. 2, the output block is illustrated in greater detail wherein, for explanatory purposes, the positive (15) and negative (16) capacitors having switches (11) for the input block are included. The adjustable capacitors (10) are totalized along the bit line and, in combination with the inverting amplifier (7) and a back-coupled capacitance (8), form an inverting amplifier, the output voltage of which is dependent upon the magnitude of the adjustable capacitors (10) and the input pulse length (2). In a second phase, a reverse voltage ramp (14) is applied to a further reference capacitor (13), until such time as the previously constituted output voltage has been suppressed, and the length is output by a comparator (9) in the form of a pulse length. It is also possible, by means of an offset capacitor (17) and a further voltage ramp (18), to introduce an offset voltage into the amplifier (7). This is particularly appropriate if both positive and negative voltages are to be output.

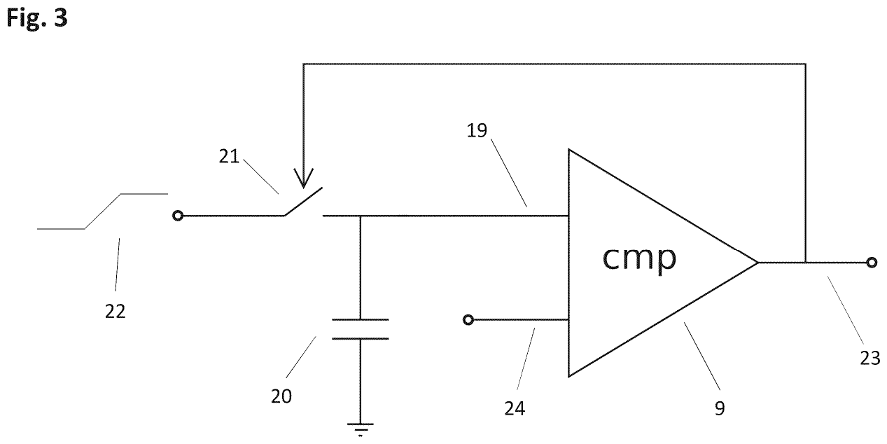

In FIG. 3, the scanning of the offset voltage is illustrated: to this end, one input (19) of the comparator is connected to a capacitor (20), which is charged by means of a voltage ramp (22). The latter is controlled by the output (23) of the comparator and a switch (21). Immediately the comparator (9) executes a switchover, the offset voltage on the voltage ramp (22) is achieved, and is saved on the capacitor (20). As both inputs are subtracted, the offset voltage is fed into the comparative phase, in which the output pulse is generated.

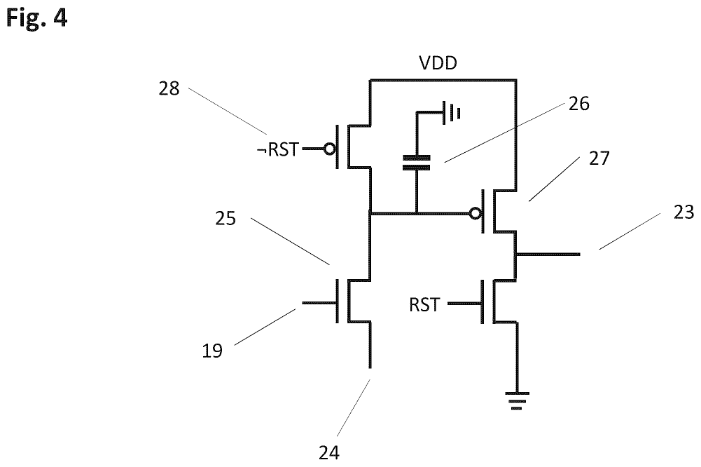

FIG. 4 represents a favorable embodiment of a comparator. Whereas conventional comparators feature either a static current consumption or a high dynamic current consumption, in this case a comparator having a low dynamic energy consumption is employed, in which consumption occurs at the switchover time point only (leakage currents aside). A capacitor (26) is pre-charged with a reset signal (28), and is then discharged by means of an input transistor (25), wherein the magnitude of discharge is dependent upon the differential of the input signals which are applied to the gate and source terminal of the input transistor (25). The output transistor (27) executes a switchover, immediately the threshold voltage of the input transistor (25) has been exceeded.

Embodiments of the disclosure can be described in view of the following clauses:

Clause 1. An assembly of a pulse-width controlled vector-matrix multiplication unit, comprising: a digital-to-time converter, which is connected to a reference time and is configured such that it receives a digital input signal and outputs a signal which is proportional to the digital input signal and is modulated over a time interval; a memory; an output interface, which is connected to a matrix of the memory and is configured to receive the weighted output signal thereof, and which outputs a digital value which is proportional to at least the reference time; and a time-to-digital converter; wherein the assembly is configured to execute a two-stage process, which comprises a first accumulation step having a starting condition for a reference discharge phase in a second step; characterized in that the network weights are comprised of programmable non-volatile adjustable capacitors; a further time-to-voltage converter is arranged down-circuit of the digital-to-time converter; and a reference capacitor for executing the discharge phase with a reference voltage ramp is provided.

Clause 2. The assembly of clause 1, characterized in that the time-to-voltage converter is comprised of a reference voltage ramp generator and a switch, which is controlled by the input pulse length, one switch end of which is connected to the reference voltage ramp generator, and the second switch end of which is connected to the input of the matrix.

Clause 3. The assembly of clause 1 or 2, characterized in that differential elements of the matrix, each having a positive (15) and a negative (16) adjustable capacitor are employed, and the positive and negative adjustable capacitors are connected to a common bit line (5) and have a respective word line (3) which, in the input block, is associated with a respective switch (11), which switches are connectively configured with reverse voltage ramps (12) and are controllable by the same input pulse lengths (2).

Clause 4. The assembly of one or more of clauses 1 to 3, characterized in that the reverse voltage ramps (14) are connected to one or more further switches, which are configured such that the reverse voltage ramps (14) can be interchanged if the input pulse length (2) carries a different sign.

Clause 5. The assembly of one or more of clauses 1 to 4, characterized in that a further offset capacitor (17) is connected to the inverting input of the amplifier (7), which is connectively configured with a further voltage ramp (18), such that an offset of the output voltage of the amplifier is achieved.

Clause 6. The assembly of one or more of clauses 1 to 5, characterized in that one comparator input (19) is connected to a capacitor (20), which is moreover connected by means of a switch (21) to a voltage ramp generator (22), wherein the switch is configured to be controlled by the comparator output (23), and the other comparator input (24) is connected to the output of the amplifier (7).

Clause 7. The assembly of one or more of clauses 1 to 6, characterized in that the comparator (9) is comprised of an input transistor (25), wherein one input of the comparator is connected to the source terminal and the other input of the comparator is connected to the gate terminal of the input transistor (25) and the drain terminal of the input transistor (25) is connected to a capacitor (26) which, optionally, can also be a stray capacitance of a transistor, and to a gate terminal of a further output transistor (27), wherein the capacitor (26) and the output of the output transistor (27) are configured such that these can be pre-charged in advance of a comparative phase.

Clause 8. The assembly of one or more of clauses 1 to 7, characterized in that a register is connected to the output of the comparator.

Clause 9. The assembly of one or more of clauses 1 to 8, characterized in that the output of the comparator is connected to a conversion table, which is configured to be controlled by a pulse generator.

Clause 10. A method for controlling an assembly as claimed in one or more of clauses 1 to 9, characterized in that, in a first phase, a voltage ramp (12) is applied to the bit lines (5) of the matrix, which is controlled by the input pulse length (2), and non-volatile adjustable capacitors (10) of the matrix along the bit line (5) are totalized and, in a second phase, via a reference capacitor (17), a reverse voltage ramp (12) is applied to the inverting input of the amplifier (7), and the comparator (9) outputs a pulse length, until such time as the output voltage of the inverting amplifier (7) is restored to the original voltage.

Clause 11. The method of clause 2, characterized in that the word lines (3) of the positive (15) and the word lines of the negative (16) adjustable capacitors are charged with reverse voltage ramps (12) although the voltage ramps (12) of the word lines (3) of a matching matrix element, comprised of a positive and a negative adjustable capacitor, are controlled by means of the same input pulse length (2).

Clause 12. The method of clause 3, characterized in that the reverse volage ramps (12) can be interchanged, such that the reverse voltage ramp is applied to the word lines of the positive and negative adjustable capacitors, in the event that the input signal (2) carries a different sign.

Clause 13. The method of clause 5, characterized in that a voltage ramp (12) is connected to one comparator input (19) which simultaneously charges a capacitor (20), and this voltage ramp (12) is interrupted immediately the switchover of the comparator output (23) is executed, and the capacitor (20) saves the scanned offset voltage.

Clause 14. The method of clause 6, characterized in that, in a first phase, the capacitor (26) and the output of the output transistor (27) are pre-charged with a reset signal (28) and, in a second phase, the capacitor (26) is discharged by means of the input transistor (25), which is controlled by the voltage differential of the two inputs, and the output transistor (27) executes a switchover, immediately the threshold voltage of the input transistor (25) is exceeded.

Embodiments of the disclosure can be described in view of the following additional clauses:

1. An apparatus, comprising: a digital-to-time converter coupled to a reference time and configured to receive a digital input signal and output a signal proportional to the digital input signal and modulated over a time interval; a memory; an output interface coupled to a matrix of the memory and configured to receive a weighted output signal, the output interface to output a digital value proportional to at least the reference time; a time-to-digital converter; a time-to-voltage converter is arranged down-circuit of the digital-to-time converter; a reference capacitor to provide a discharge phase based on a reference voltage ramp; and programmable non-volatile adjustable capacitors associated with the matrix of the memory and to provide one or more network weights; wherein the apparatus is configured to execute a two-stage process comprising a first accumulation step having a starting condition for a reference discharge phase associated with a second step.

2. The apparatus as claimed in claim 1, wherein the time-to-voltage converter is comprised of a reference voltage ramp generator and a switch, controlled at least in part based on an input pulse length, one switch end of the switch being connected to the reference voltage ramp generator, and another switch end of the switch being connected to an input of the matrix.

3. The apparatus as claimed in claim 1, wherein the matrix includes differential elements, each having a positive and negative adjustable capacitors, the positive and negative adjustable capacitors are connected to a common bit line and each have a word line, wherein each word line includes a switch configured to connect with reverse voltage ramps and is controlled by an input pulse length.

4. The apparatus as claimed in claim 3, wherein the reverse voltage ramps are connected to one or more further switches, the reverse voltage ramps interchangeable when the input pulse length carries a different sign.

5. The apparatus as claimed in claim 1, further comprising an offset capacitor connected to an inverting input of an amplifier.

6. The apparatus as claimed in claim 1, further comprising a comparator input (coupled to a capacitor, the capacitor connected via a switch to a voltage ramp generator, wherein the switch is configured to be controlled by a comparator output, and an another comparator input is connected to an output of an amplifier.

7. The apparatus as claimed in claim 1, further comprising a comparator including an input transistor, wherein an input of the comparator is connected to a source terminal of the input transistor and another input of the comparator is connected to a gate terminal of the input transistor, and a drain terminal of the input transistor is connected to a capacitor, wherein the capacitor and an output of an output transistor are configured to be pre-charged in advance of a comparative phase.

8. The apparatus as claimed in claim 1, further comprising a register coupled to an output of a comparator.

9. The apparatus as claimed in claim 8, the output of the comparator is connected to a conversion table to be controlled by a pulse generator.

10. A method for controlling a matrix-based assembly comprising non-volatile adjustable capacitors, the method comprising: applying, in a first phase, a voltage ramp to bit lines of a matrix, wherein the voltage ramp is controlled by an input pulse length; totalizing, along the bit lines, the non-volatile adjustable capacitors of the matrix in response to the applied voltage ramp; applying, in a second phase, a reverse voltage ramp via a reference capacitor to an inverting input of an amplifier; and outputting a pulse length from a comparator until an output voltage of the inverting amplifier is restored to an original voltage.

11. The method of claim 10, further comprising: charging word lines of positive and negative adjustable capacitors with reverse voltage ramps, wherein the voltage ramps of the word lines of a matching matrix element, comprising the positive and negative adjustable capacitors, are controlled by a common input pulse length.

12. The method of claim 10, further comprising: interchanging the reverse voltage ramps such that the reverse voltage ramp is applied to word lines of positive and negative adjustable capacitors based on a sign of the input signal.

13. The method of claim 10, further comprising: applying a voltage ramp to a comparator input, wherein the voltage ramp simultaneously charges a capacitor; interrupting the voltage ramp immediately upon switchover of the comparator output; and storing, in the capacitor, an offset voltage detected at a moment of comparator switchover.

14. The method of claim 10, further comprising: pre-charging, in a first phase, a capacitor and an output of an output transistor with a reset signal; discharging, in a second phase, the capacitor via an input transistor controlled by a voltage differential between two inputs; and switching the output transistor when a threshold voltage of the input transistor is exceeded.

15. An assembly comprising a pulse-width controlled vector-matrix multiplication unit, the assembly comprising: a digital-to-time converter connected to a reference time and configured to receive a digital input signal and to output a signal that is proportional to the digital input signal and modulated over a time interval; a memory; an output interface connected to a matrix of the memory, the output interface configured to receive a weighted output signal of the matrix and to output a digital value that is proportional to at least the reference time; a time-to-digital converter; a further time-to-voltage converter arranged downstream of the digital-to-time converter; and a reference capacitor configured to execute a discharge phase using a reference voltage ramp, wherein the assembly is configured to execute a two-stage process comprising a first accumulation step having a starting condition for a reference discharge phase in a second step, and wherein network weights of the matrix are comprised of programmable non-volatile adjustable capacitors.

16. The assembly of claim 15, wherein the time-to-voltage converter comprises a reference voltage ramp generator and a switch controlled by an input pulse length, the switch having a first terminal connected to the reference voltage ramp generator and a second terminal connected to an input of the matrix.

17. The assembly of claim 15, wherein the matrix comprises differential elements each having a positive adjustable capacitor and a negative adjustable capacitor, the positive and negative adjustable capacitors being connected to a common bit line and each associated with a respective word line, wherein each word line is associated, in an input block, with a respective switch configured to be connected to reverse voltage ramps and controlled by a common input pulse length.

18. The assembly of claim 15, further comprising one or more switches connected to reverse voltage ramps, the switches configured to interchange the reverse voltage ramps in response to a sign of an input pulse length.

19. The assembly of claim 15, further comprising an offset capacitor connected to an inverting input of an amplifier and configured in connection with a further voltage ramp to introduce an offset in an output voltage of the amplifier.

20. The assembly of claim 15, further comprising a conversion table connected to the output of comparator, the conversion table configured to be controlled by a pulse generator.

### LIST OF REFERENCE NUMBERS

1—Input block
2—Input pulse
3—Word lines
4—Matrix of non-volatile storage components
5—Bit lines
6—Output blocks
7—Amplifier
8—Back-coupled capacitance
9—Comparator
10—Adjustable capacitors
11—Switch for input block
12—Voltage ramp (generator)
13—Reference capacitor
14—Reverse voltage ramp for reference
15—Positive adjustable capacitor
16—Negative adjustable capacitor
17—Offset capacitor
18—Voltage ramp for offset capacitor
19—First comparator input
20—Capacitor for comparator
21—Switch for comparator
22—Voltage ramp generator for comparator
23—Comparator output
24—Second comparator input
25—Input transistor
26—Capacitor in comparator
27—Output transistor
28—Reset signal

What is claimed is:

1. An apparatus, comprising:
a digital-to-time converter coupled to a reference time and configured to receive a digital input signal and output a signal proportional to the digital input signal and modulated over a time interval;
a memory;
an output interface coupled to a matrix of the memory and configured to receive a weighted output signal, the output interface to output a digital value proportional to at least the reference time;
a time-to-digital converter;
a time-to-voltage converter is arranged down-circuit of the digital-to-time converter;
a reference capacitor to provide a discharge phase based on a reference voltage ramp; and
programmable non-volatile adjustable capacitors associated with the matrix of the memory and to provide one or more network weights,
wherein the apparatus is configured to execute a two-stage process comprising a first accumulation step having a starting condition for a reference discharge phase associated with a second step.

2. The apparatus as claimed in claim 1, wherein the time-to-voltage converter is comprised of a reference voltage ramp generator and a switch, controlled at least in part based on an input pulse length, one switch end of the switch being connected to the reference voltage ramp generator, and another switch end of the switch being connected to an input of the matrix.

3. The apparatus as claimed in claim 1, wherein the matrix includes differential elements, each having a positive and negative adjustable capacitors, the positive and negative adjustable capacitors are connected to a common bit line and each have a word line, wherein each word line includes a switch configured to connect with reverse voltage ramps and is controlled by an input pulse length.

4. The apparatus as claimed in claim 3, wherein the reverse voltage ramps are connected to one or more further switches, the reverse voltage ramps interchangeable when the input pulse length carries a different sign.

5. The apparatus as claimed in claim 1, further comprising an offset capacitor connected to an inverting input of an amplifier.

6. The apparatus as claimed in claim 1, further comprising a comparator input coupled to a capacitor, the capacitor connected via a switch to a voltage ramp generator, wherein the switch is configured to be controlled by a comparator output, and an another comparator input is connected to an output of an amplifier.

7. The apparatus as claimed in claim 1, further comprising a comparator including an input transistor, wherein an input of the comparator is connected to a source terminal of the input transistor and another input of the comparator is connected to a gate terminal of the input transistor, and a drain terminal of the input transistor is connected to a capacitor, wherein the capacitor and an output of an output transistor are configured to be pre-charged in advance of a comparative phase.

8. The apparatus as claimed in claim 1, further comprising a register coupled to an output of a comparator.

9. The apparatus as claimed in claim 8, the output of the comparator is connected to a conversion table to be controlled by a pulse generator.

10. A method for controlling a matrix-based assembly comprising non-volatile adjustable capacitors, the method comprising:
applying, in a first phase, a voltage ramp to bit lines of a matrix, wherein the voltage ramp is controlled by an input pulse length;
totalizing, along the bit lines, the non-volatile adjustable capacitors of the matrix in response to the applied voltage ramp;
applying, in a second phase, a reverse voltage ramp via a reference capacitor to an inverting input of an amplifier; and
outputting a pulse length from a comparator until an output voltage of the inverting amplifier is restored to an original voltage.

11. The method of claim 10, further comprising charging word lines of positive and negative adjustable capacitors with reverse voltage ramps, wherein the voltage ramps of the word lines of a matching matrix element, comprising the positive and negative adjustable capacitors, are controlled by a common input pulse length.

12. The method of claim 10, further comprising interchanging the reverse voltage ramps such that the reverse voltage ramp is applied to word lines of positive and negative adjustable capacitors based on a sign of the input signal.

13. The method of claim 10, further comprising:
applying a voltage ramp to a comparator input, wherein the voltage ramp simultaneously charges a capacitor;
interrupting the voltage ramp immediately upon switchover of the comparator output; and
storing, in the capacitor, an offset voltage detected at a moment of comparator switchover.

14. The method of claim 10, further comprising:
pre-charging, in a first phase, a capacitor and an output of an output transistor with a reset signal;
discharging, in a second phase, the capacitor via an input transistor controlled by a voltage differential between two inputs; and
switching the output transistor when a threshold voltage of the input transistor is exceeded.

15. An assembly comprising a pulse-width controlled vector-matrix multiplication unit, the assembly comprising:
a digital-to-time converter connected to a reference time and configured to receive a digital input signal and to output a signal that is proportional to the digital input signal and modulated over a time interval;
a memory;
an output interface connected to a matrix of the memory, the output interface configured to receive a weighted output signal of the matrix and to output a digital value that is proportional to at least the reference time;
a time-to-digital converter;
a further time-to-voltage converter arranged downstream of the digital-to-time converter; and
a reference capacitor configured to execute a discharge phase using a reference voltage ramp,
wherein the assembly is configured to execute a two-stage process comprising a first accumulation step having a starting condition for a reference discharge phase in a second step, and
wherein network weights of the matrix are comprised of programmable non-volatile adjustable capacitors.

16. The assembly of claim 15, wherein the time-to-voltage converter comprises a reference voltage ramp generator and a switch controlled by an input pulse length, the switch having a first terminal connected to the reference voltage ramp generator and a second terminal connected to an input of the matrix.

17. The assembly of claim 15, wherein the matrix comprises differential elements each having a positive adjustable capacitor and a negative adjustable capacitor, the positive and negative adjustable capacitors being connected to a common bit line and each associated with a respective word line, wherein each word line is associated, in an input block, with a respective switch configured to be connected to reverse voltage ramps and controlled by a common input pulse length.

18. The assembly of claim 15, further comprising one or more switches connected to reverse voltage ramps, the switches configured to interchange the reverse voltage ramps in response to a sign of an input pulse length.

19. The assembly of claim 15, further comprising an offset capacitor connected to an inverting input of an amplifier and configured in connection with a further voltage ramp to introduce an offset in an output voltage of the amplifier.

20. The assembly of claim 15, further comprising a conversion table connected to the output of comparator, the conversion table configured to be controlled by a pulse generator.
